(19) United States
(12) Patent Application Publication
(10) Pub. No.: US 2016/0094258 A1
(43) Pub. Date: Mar. 31, 2016

(54) TRANSCEIVER MODULE AND COMMUNICATION APPARATUS INCLUDING THE SAME

(71) Applicant: ELECTRONICS AND TELECOMMUNICATIONS RESEARCH INSTITUTE, Daejeon (KR)

(72) Inventors: Hyun-cheol BAE, Daejeon (KR); Yong Sung EOM, Daejeon (KR); Haksun LEE, Daejeon (KR); KWANG-SEONG CHOI, Daejeon (KR)

(73) Assignee: ELECTRONICS AND TELECOMMUNICATIONS RESEARCH INSTITUTE, Daejeon (KR)

(21) Appl. No.: 14/857,818

(22) Filed: Sep. 17, 2015

(30) Foreign Application Priority Data
Sep. 25, 2014 (KR) 10-2014-0128200
May 7, 2015 (KR) 10-2015-0063980

(51) Int. Cl. H04B 1/38; H05K 1/18; H05K 1/11; H05K 1/02

(52) U.S. Cl. CPC H04B 1/38; H05K 1/021; H05K 1/181; H05K 1/111; H05K 2201/10219; H05K 2201/10007; H05K 2201/10098; H05K 2201/10151; H05K 2201/10287

(57) ABSTRACT

Provided are a transceiver module and a communication apparatus including the same. The transceiver module includes a lower substrate, a thermoelectric device on the lower substrate, and an upper substrate which is disposed on the thermoelectric device and on which high frequency devices cooled by the thermoelectric device are mounted. The upper substrate includes a ceramic printed circuit board (PCB).

### CROSS-REFERENCE TO RELATED APPLICATIONS

This U.S. non-provisional patent application claims priority under 35 U.S.C. §119 of Korean Patent Application Nos. 10-2014-0128200, filed on Sep. 25, 2014, and 10-2015-0063980, filed on May 7, 2015, the entire contents of which are hereby incorporated by reference.

### BACKGROUND

The present disclosure herein relates to a communication apparatus and more particularly, to a transceiver module and a communication apparatus including the same.

In recent, a transceiver module has shown high performance. The transceiver module has been developed in various forms from a passive array to an active array. A general radar transceiver module may include an insulating substrate on which high frequency devices are mounted and a heat-radiating substrate under the insulating substrate. The insulating substrate may be several millimeters (mm) thick. The heat-radiating substrate may cool the insulating substrate by using a dry method. Nevertheless, the high frequency devices may generate heat because they generate a radar signal having great power. The transceiver module may be degraded by heat. Thus, heat radiation from the high frequency device may decrease the lifespan of the transceiver module.

### SUMMARY

Example embodiment of the inventive concept provides a transceiver module capable of maximizing cooling efficiency and a communication apparatus including the same.

Example embodiment of the inventive concept provides a transceiver module capable of increasing a lifespan and a communication apparatus including the same.

According to example embodiment of the inventive concept, a transceiver module including a lower substrate; a thermoelectric device on the lower substrate; and an upper substrate disposed on the thermoelectric device, the upper substrate mounting high frequency devices cooled by the thermoelectric device and including a ceramic printed circuit board (PCB).

According to example embodiment of the inventive concept, a communication apparatus includes a display module; a control module controlling the display module; and a transceiver module configured to transmit a transmission signal provided from the control module and provide a reception signal to the control module, a lower substrate; a thermoelectric device on the lower substrate; and an upper substrate disposed on the thermoelectric device, the upper substrate mounting high frequency devices cooled by the thermoelectric device and including a ceramic printed circuit board (PCB).

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a diagram schematically showing a communication apparatus of the inventive concept;

FIG. 2 is a plain view showing an example of a transceiver module in FIG. 1;

FIG. 3 is a cross-sectional view of a printed circuit board, a high-power amplifier, a low-power amplifier, a circulator, a cooling unit, and a first temperature sensor in FIG. 2.

FIG. 4 is a cross-sectional view of an example of a transceiver module in FIG. 3;

FIG. 5 is a cross-sectional view of an example of a transceiver module in FIG. 3;

FIG. 6 is a cross-sectional view of an example of a transceiver module in FIG. 3;

FIG. 7 is a plain view showing an example of a transceiver module of the inventive concept; and

FIG. 8 is a cross-sectional view of a printed circuit board, a transmission unit, a reception unit, a circulator, a cooling unit, and a second temperature sensor in FIG. 7.

### DETAILED DESCRIPTION

Exemplary embodiments of the inventive concept are described below in detail with reference to the accompanying drawings. The effects and features of the inventive concept, and implementation methods thereof will be clarified through following embodiments to be described in detail with reference to the accompanying drawings. However, the inventive concept is not limited to embodiments to be described below but may also be implemented in other forms. Rather, these embodiments are provided so that this disclosure can be thorough and complete and fully convey the scope of the inventive concept to a person skilled in the art, and the inventive concept is only defined by the scopes of claims. The same reference numerals throughout the disclosure refer to the same components.

The terms used herein are only for explaining embodiments and not intended to limit the inventive concept. The terms in a singular form in the disclosure also include plural forms unless otherwise specified. The terms used herein “comprises” and/or “comprising” do not exclude the presence or addition of one or more additional components, steps, operations and/or elements other than the components, steps, operations and/or elements that are mentioned. Also, the terms chamber, thin film, and coating in the disclosure may be understood as general semiconductors and device terms. Since the following description presents an exemplary embodiment, the reference numerals presented according to the order of the description are not limited to the order.

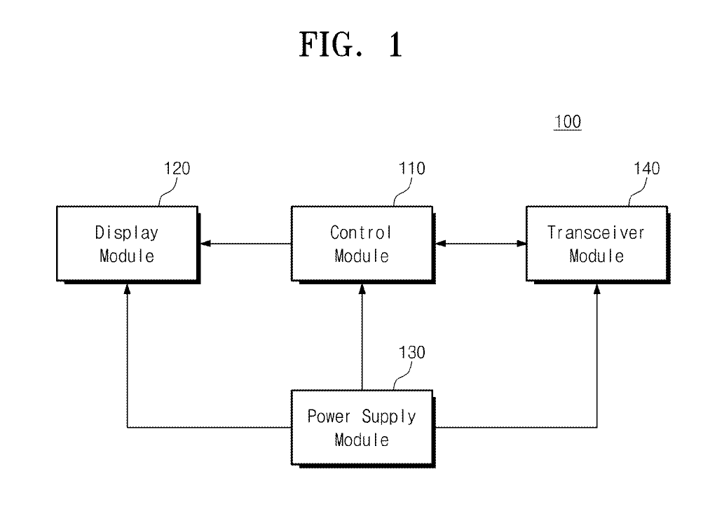

FIG. 1 schematically shows a communication apparatus 100 of the inventive concept.

Referring to FIG. 1, the communication apparatus 100 may be a radar communication apparatus. According to an example, the communication apparatus 100 may include a control module 110, a display module 120, a power supply module 130, and a transceiver module 140. The control module 110 may control the display module 120 and the transceiver module 140. The transceiver module 140 may transmit and receive a radar signal. The display module 120 may display communications according to the radar signal. The display module 120 may include a liquid crystal display (LCD) or organic light-emitting diode (OLED). The power supply module 130 may supply power to the control module 110, the display module 120 and the transceiver module 140.

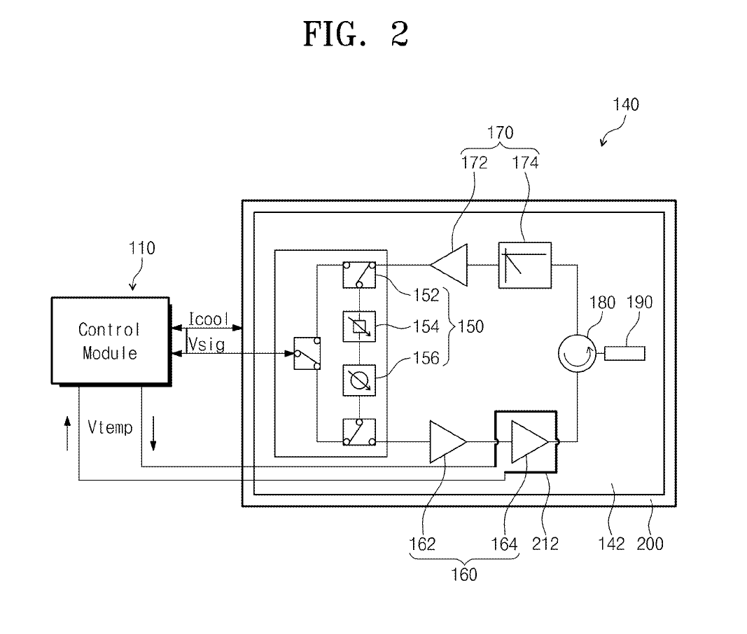

FIG. 2 shows an example of the transceiver module 140 in FIG. 1.

Referring to FIG. 2, the transceiver module 140 may include a printed circuit board (PCB) 142, a core chip 150, a transmission unit 160, a reception unit 170, a circulator 180, an antenna 190, a first cooling unit 200, and a first temperature sensor 212.

The core chip 150, the transmission unit 160, the reception unit 170, the circulator 180, the antenna 190, and the first temperature sensor 212 that are high frequency devices may mount the PCB 142. The core chip 150, the transmission unit 160, the reception unit 170, the circulator 180, and the antenna 190 may be high frequency devices.

The core chip 150 may be connected to the control module 110. The core chip 150 may process the radar signals V_{sig} of transmission and reception signals. According to an example, the core chip 150 may include a plurality of switching devices 152, a phase shifter 154, and an attenuator 156. The switching devices 152 may be disposed at the front and rear ends of the phase shifter 154 and the attenuator 156. The switching devices 152 may control the input and output of the transmission and reception signals. The phase shifter 154 may delay the input and output times between the transmission and reception signals. For example, when the transmission signal is output from the core chip 150, the phase shifter 154 may temporarily delay the reception signal. The attenuator 156 may adjust the signal levels of the transmission and reception signals. The phase shifter 154 and the attenuator 156 may be connected serially.

The transmission unit 160 may be connected between the core chip 150 and the circulator 180. The transmission unit 160 may output the transmission signal. According to an example, the transmission unit 160 may include a driver 162 and a high power amplifier 164. The driver 162 may be connected to the core chip 150. The driver 162 may adjust the frequency of the transmission signal according to the time. Alternatively, the driver 162 may switch the transmission signal every unit time. The high power amplifier 164 may amplify the size of the transmission signal. For example, the high power amplifier 164 may be operated by a high current of about 1 A to about 10 A. The high current may be a reason for heat radiation from the high power amplifier 164.

The reception unit 170 may be connected in parallel to the transmission unit 160 between the core chip 150 and the circulator 180. The reception unit 170 may input the reception signal to the core chip 150. According to an example, the reception unit 170 may include a limiter 172 and a low power amplifier 174. The limiter 172 may be connected to the circulator 180. The limiter 172 may be a device that controls the maximum level of the reception signal. The low power amplifier 174 may be connected between the limiter 172 and the core chip. The low power amplifier 174 may be operated by a current of about several tens of mmA to about several hundreds of mmA.

The circulator 180 may connect the transmission unit 160 and the reception unit 170 to the antenna 190. The circulator 180 may transmit the transmission signal between the transmission unit 160 and the antenna 190. Alternatively, the circulator 180 may transmit the reception signal between the antenna 190 and the reception unit 170. The transmission and reception signals may be transmitted by the circulator 180 without signal loss. The circulator 180 may also be replaced with a transmission and reception switch.

The antenna 190 may output the transmission signal wirelessly. The antenna 190 may receive a wireless reception signal.

The first cooling unit 200 may cool the PCB 142. The first cooling unit 200 may remove the heat of the high power amplifier 164. The first cooling unit 200 is described below in more detail.

The first temperature sensor 212 may be disposed adjacent to the high power amplifier 164. According to an example, the first temperature sensor 212 may surround the high power amplifier 164. The first temperature sensor 212 may detect the temperature of the high power amplifier 164. The first temperature sensor 212 may be connected to the control module 110.

The control module 110 may monitor the temperature of the high power amplifier 164. The control module 110 may receive the temperature sensing voltage Vₜₑₘₚ of the first temperature sensor 212 to determine the temperature of the high power amplifier 164. The control module 110 may control the first cooling unit 200 according to the temperature of the high power amplifier 164. For example, the control module 110 may provide, a cooling control current I_{cool} proportional to the temperature of the high power amplifier 164, to the cooling unit 200. The size of the cooling control current I_{cool} may increase in proportion to the temperature of the high power amplifier 164. The high power amplifier 164 and the PCB 142 may be controlled to have a certain temperature.

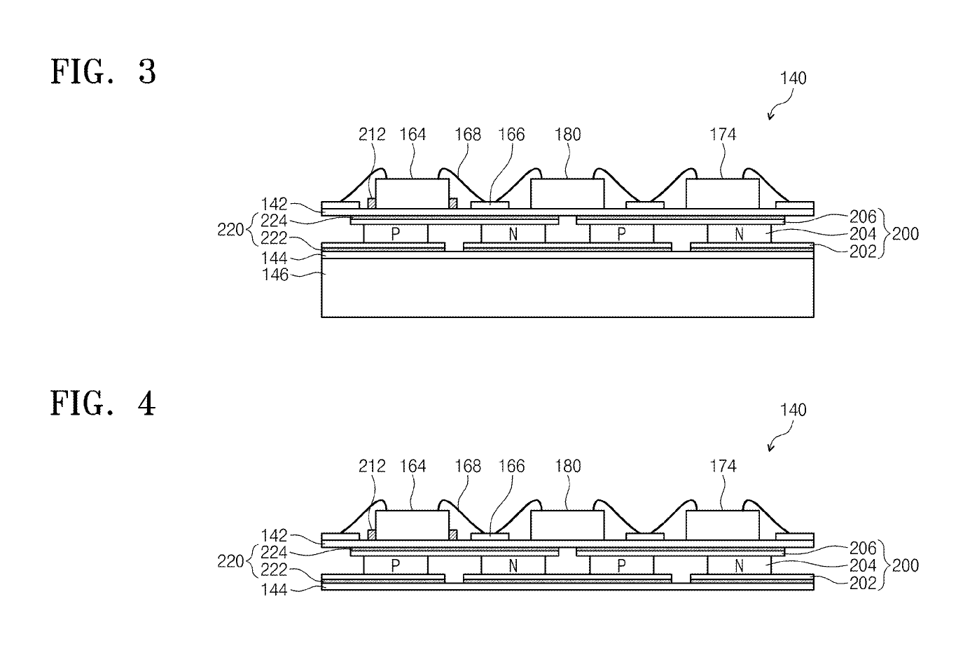

FIG. 3 shows the PCB 142, the high power amplifier 164, the low power amplifier 174, the circulator 180, the first cooling unit 200, and the first temperature sensor 212 in FIG. 2.

Referring to FIG. 3, the high power amplifier 164, the low power amplifier 174, and the circulator 180 may be disposed on the PCB 142. Each of the high power amplifier 164, the low power amplifier 174, and the circulator 180 may be disposed between pads 166. The pads 116 may be disposed on the PCB 142. Bonding wires 168 may connect the pads 166 to the high power amplifier 164, the low power amplifier 174, and the circulator 180.

The first temperature sensor 212 may be disposed between the high power amplifier 164 and the pads 166. According to an example, the first temperature sensor 212 may include a thermocouple. The thermocouple may sense a temperature by seebeck effect. For example, the thermocouple may include a nickel chrome alloy line. The first temperature sensor 212 may have a thickness of about 100 μm to about 1 mm. The high power amplifier 164 and the pads 166 may be disposed at an interval equal to or greater than the thickness of the first temperature sensor 212. A resin may be provided between the first temperature sensor 212 and the bonding wires 168, though not shown. The resin may insulate the first temperature sensor 212 from the bonding wires 168.

The PCB 142 may be disposed on the first cooling unit 200. The PCB 142 may include a ceramic PCB. The ceramic PCB may have an excellent insulating characteristic in comparison to a general plastic PCB. In addition, the ceramic PCB may have a thin thickness in comparison to the plastic PCB.

The first cooling unit 200 may include a thermoelectric (TEC) device. For example, when a current is supplied to the first cooling unit 200, the first cooling unit 200 may cool the PCB 142. The first cooling unit 200 may be cooled by Peltier effect. The first cooling unit 200 may include lower electrodes 202, first impurity semiconductor layers 204, and upper electrodes 206. The lower electrodes 202 and the upper electrodes 206 may be disposed under and on the first impurity semiconductor layers 204, respectively. The first impurity semiconductor layers 204 may have P type or N type conductivity. The first impurity semiconductor layers 204 of the P and N types may be connected serially to the lower electrodes 202 and the upper electrodes 206. When a forward current is supplied to the first impurity semiconductor layers 204, the lower electrodes 202 may be heated but the upper electrodes 206 may be cooled. The upper electrodes 206 may cool the high power amplifier 164, the low power amplifier 174, and the circulator 180.

A first lower substrate 144 may be disposed under the lower electrodes 202. The first lower substrate 144 may have the same thickness as the PCB 142. The first lower substrate 144 may include a ceramic substrate. The PCB 142 may become the upper substrate of the cooling unit 200 on the first lower substrate 144. The PCB 142 may and the first lower substrate 144 may protect the cooling unit 200.

A first paste 220 may fix the first cooling unit 200 between the PCB 142 and the lower substrate 114. The first paste 220 may include solder. The first paste 220 may include a first lower paste 222 and a first upper paste 224. The first lower paste 222 may fix the first cooling unit 200 to the lower substrate 144. The first upper paste 224 may include the first cooling unit 200 and the PCB 142.

A heat-radiating substrate 146 may be disposed under the lower substrate 144. The heat-radiating substrate 146 may include a metal plate. T first lower substrate 144 may insulate the lower electrodes 202 from the heat-radiating substrate 146.

When the high power amplifier 164 is cooled, the heat-radiating substrate 146 may be heated. The heat-radiating substrate 146 may be cooled in the air. The heat-radiating substrate 146 and the first lower substrate 144 may be bonded by a paste, though not shown.

FIG. 4 shows an example of the transceiver module 140 in FIG. 3.

Referring to FIGS. 3 and 4, the heat-radiating substrate 146 of the transceiver module 140 may be removed. The high power amplifier 164, the low power amplifier 174, the circulator 180, the pads 166, the bonding wires 168, the PCB 142, the first cooling unit 200, the first paste 220, and the first lower substrate 144 may be the same as in FIG. 3. The heat-radiating substrate 146 removed may decrease the thickness of the transceiver module 140.

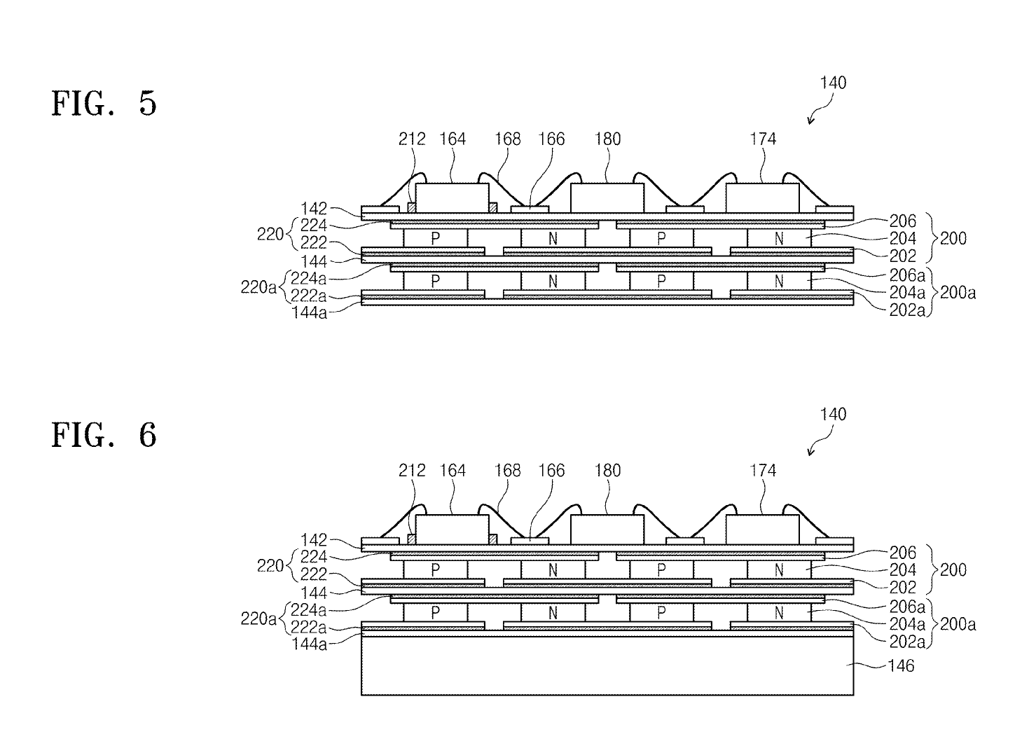

FIG. 5 shows an example of the transceiver module 140 in FIG. 3.

Referring to FIG. 5, the transceiver module 140 may further include at least one second cooling unit 200a and a second lower substrate 144a. The second cooling unit 200a may be disposed under the first lower substrate 144. The second cooling unit 200a may cool the first lower substrate 144. The second cooling unit 200a may be connected serially or in parallel to the first cooling unit 200. The second cooling unit 200a may have the same disposition as the first cooling unit 200. For example, the second cooling unit 200a may include second lower electrodes 202a, second impurity semiconductor layers 204a, and second upper electrodes 206a. The second lower substrate 144a may be disposed under the second lower electrodes 202a. A second paste 220a may fix the second cooling unit 200a between the first lower substrate 144 and the second lower substrate 144a. The second paste 220a may include a second lower paste 222a and a second upper paste 224a. The second lower paste 222a may fix the second cooling unit 200a to the second lower substrate 144a. The second upper paste 224a may fix the second cooling unit 200a to the first lower substrate 144. The high power amplifier 164, the low power amplifier 174, the circulator 180, the pads 166, the bonding wires 168, the PCB 142, the first cooling unit 200, the first paste 220, and the first lower substrate 144 may be the same as in FIG. 3.

FIG. 6 shows an example of the transceiver module 140 in FIG. 3.

Referring to FIG. 6, the heat-radiating substrate 146 may be disposed under the second lower substrate 144a. The heat-radiating substrate 146 may cool the second lower substrate 144a. The heat-radiating substrate 146 and the second lower substrate 144a may be fixed by a paste, though not shown. The high power amplifier 164, the low power amplifier 174, the circulator 180, the pads 166, the bonding wires 168, the PCB 142, the first cooling unit 200, the first paste 220, and the first lower substrate 144 may be the same as in FIG. 3.

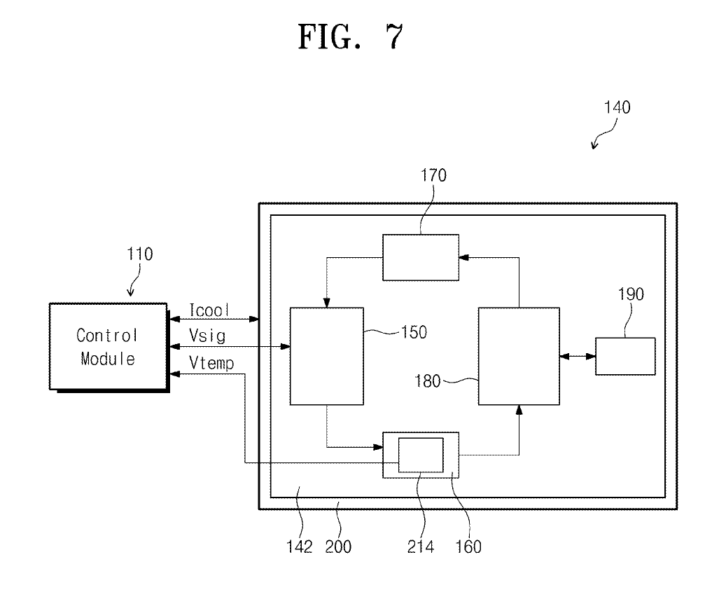

FIG. 7 shows an example of the transceiver module 140 of the inventive concept.

Referring to FIG. 7, the transceiver module 140 of the inventive concept may include a second temperature sensor 214. The second temperature sensor 214 may be disposed on the transmission unit 160. The second temperature sensor 214 may include a band gap reference circuit. The second temperature sensor 214 may provide a temperature sensing voltage Vₜₑₘₚ to the control module 110. The control module 110 may control the first cooling unit 200 according to the temperature of the transmission unit 160. The temperature of the transmission unit 160 may be adjusted by the first cooling unit 200. Alternatively, the control module 110 may output a transmission signal to the core chip 150. The core chip 150 may be connected to the transmission unit 160 and the reception unit 170. The reception unit 170 may provide a reception signal to the core chip 150 and the control module 110. The transmission unit 160 and the reception unit 170 may be connected to the circulator 180. The circulator 180 may be connected to an antenna.

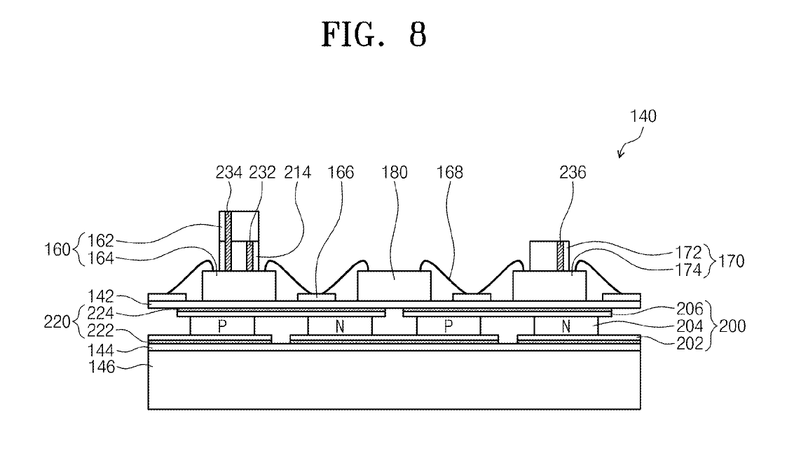

FIG. 8 shows the PCB 142, the transmission unit 160, the reception unit 170, the circulator 180, the first cooling unit 200, and the second temperature sensor 214 in FIG. 7.

Referring to FIG. 8, the second temperature sensor 214 may be provided to the transmission unit 160. For example, the second temperature sensor 214 may be disposed between the driver 162 of the transmission unit 160 and the high power amplifier 164. The PCB 142, the circulator 180, the first cooling unit 200, the first lower substrate 144, and the heat-radiating substrate 146 may be the same as in FIG. 3.

The high power amplifier 164 may be mounted on the PCB 142. The bonding wires 168 may connect between the high power amplifier 164 and the pads 166. The pads 166 may be mounted on the PCB 142. Alternatively, the pads 116 may be the wirings of the PCB 142. The second temperature sensor 214 may be disposed on the high power amplifier 164. The driver 162 may be disposed on the second temperature sensor 214. The second temperature sensor 214 may have first penetration electrodes 232. The first penetration electrodes 232 may be connected to the high power amplifier 164. The driver 162 may be disposed on the second temperature sensor 214. The driver 162 may have a second penetration electrode 234. The second penetration electrode 234 may be connected to one of the first penetration electrodes 232.

The limiter 172 may be disposed on the low power amplifier 174. The limiter 172 may have a third penetration electrode 236. The third penetration electrode 236 may be connected to the low power amplifier 174. The low power amplifier 174 may be connected to the pads 166 by the bonding wires. 168

As described above, the transceiver module according to an exemplary embodiment of the inventive concept may include a ceramic PCB on which high frequency devices are mounted and which is fixed to on the cooling unit of the thermoelectric device. The ceramic PCB may maximize the cooling efficiency of the cooling unit. The lifespan of the high frequency devices may increase.

While embodiments of the inventive concept are described with reference to the accompanying drawings, a person skilled in the art may understand that the inventive concept may be practiced in other particular forms without changing technical spirits or essential characteristics. Therefore, the above-described embodiments should be understood as illustrative and not limitative in every aspect.

What is claimed is:

1. A transceiver module comprising:
a lower substrate;
a thermoelectric device on the lower substrate; and
an upper substrate disposed on the thermoelectric device, the upper substrate mounting high frequency devices cooled by the thermoelectric device and including a ceramic printed circuit board (PCB).

2. The transceiver module of claim 1, wherein the high frequency devices comprise:
a high power amplifier configured to amplify a first high frequency signal; and
a low power amplifier configured to amplify, a second high frequency signal different from the first high frequency signal, to a power lower than that of the high power amplifier.

3. The transceiver module of claim 2, further comprising a first temperature sensor disposed adjacent to the high power amplifier to sense a temperature of the high power amplifier.

4. The transceiver module of claim 3, wherein the first temperature sensor comprises a thermocouple.

5. The transceiver module of claim 3, further comprising:
pads mounted on the upper substrate adjacent to the high power amplifier; and
bonding wires configured to connect the pads and the high power amplifier,
wherein the first temperature sensor is disposed on the ceramic PCB between the pads and the high power amplifier.

6. The transceiver module of claim 2, wherein the high frequency devices further comprise a driver on the high power amplifier.

7. The transceiver module of claim 6, further comprising a second temperature sensor disposed between the high power amplifier and the driver to sense a temperature of the high power amplifier.

8. The transceiver module of claim 7, wherein the second temperature sensor comprises a band gap reference circuit.

9. The transceiver module of claim 7, wherein the second temperature sensor has a penetration electrode connecting the high power amplifier and the driver.

10. The transceiver module of claim 1, wherein the lower substrate comprises a ceramic substrate.

11. The transceiver module of claim 10, further comprising a heat-radiating substrate disposed under the lower substrate and configured to cool the thermoelectric device,
wherein the heat-radiating substrate comprises a metal plate.

12. A communication apparatus comprising:
a display module;
a control module controlling the display module; and
a transceiver module configured to transmit a transmission signal provided from the control module and provide a reception signal to the control module,
a lower substrate;
a thermoelectric device on the lower substrate; and
an upper substrate disposed on the thermoelectric device, the upper substrate mounting high frequency devices cooled by the thermoelectric device and including a ceramic printed circuit board (PCB).

13. The communication apparatus of claim 12, wherein the high frequency devices comprise:
an antenna;
a core chip disposed between the antenna and the control module and configured to process the transmission signal and the reception signal;
a circulator configured to transmit the transmission signal and the reception signal between the core chip and the antenna;
a transmission unit configured to process the transmission signal between the circulator and the core chip; and
a reception unit connected in parallel to the transmission unit between the circulator and the core and configured to process the reception signal.

14. The communication apparatus of claim 13, wherein the transmission unit comprises:
a driver configured to drive the transmission signal; and
A high power amplifier disposed between the driver and the antenna and configured to amplify the transmission signal.

15. The communication apparatus of claim 14, further comprising a first temperature sensor mounted on the upper substrate adjacent to the high power amplifier and connected to the control module.

16. The communication apparatus of claim 15, further comprising:
pads mounted on the upper substrate adjacent to the high power amplifier; and
bonding wires configured to connect the pads and the high power amplifier,
wherein the first temperature sensor is disposed on the ceramic PCB between the pads and the high power amplifier.

17. The communication apparatus of claim 14, further comprising a second temperature sensor disposed on the high power amplifier to provide a temperature sensing voltage of the high power amplifier to the control module.

18. The communication apparatus of claim 17, wherein the second temperature sensor has first penetration electrodes connected to the high power amplifier.

19. The communication apparatus of claim 18, wherein the driver is disposed on the second temperature sensor.

20. The communication apparatus of claim 19, wherein the driver has a second penetration electrode connected to the first penetration electrodes.
